(19) United States
(12) Patent Application Publication
(10) Pub. No.: US 2014/0185834 A1
(43) Pub. Date: Jul. 3, 2014

(54) VOLUME CONTROL APPARATUS

(71) Applicants: Andreas Frömel, Kirchseeon (DE); Lars Cieslak, Ulm (DE)

(72) Inventors: Andreas Frömel, Kirchseeon (DE); Lars Cieslak, Ulm (DE)

(73) Assignee: Nokia Corporation, Espoo (FI)

(21) Appl. No.: 14/117,748

(22) PCT Filed: Apr. 11, 2011
(86) PCT No.: PCT/IB2011/051548

§ 371 Date: Nov. 14, 2013

(51) Int. Cl. H03G 3/02

(52) U.S. Cl. CPC H03G 3/02
USPC 381/109

(57) ABSTRACT

An apparatus comprising a force sensor configured to determine a force exerted on the apparatus; and a volume controller configured to control a volume of an audio output dependent on the force.

### TECHNICAL FIELD OF THE APPLICATION

The present application relates to volume control apparatus in audio devices. The invention further relates to, but is not limited to volume control apparatus in portable audio devices.

### BACKGROUND TO THE APPLICATION

Audio processing and in particular audio processing in mobile devices have been a growing area in recent years.

Audio devices typically feature a volume control or controller enabling the user to manually adjust the volume of the audio signal output by the device. These have generally been mechanical in nature. For example the volume control knob or dial where the turning of the knob causes a change in the volume, a slider where the position of the slider defined the volume or a volume button or buttons whereby depressing the button causes the volume to go up or down. Volume buttons have generally replaced the knob, dial or slider method of volume control as it is generally cheaper and less prone to mechanical failure such as due to foreign object contamination on the moving parts.

In some mobile audio devices with touch screen user interfaces, the mechanical volume control switches, sliders and dials have been replaced with touch screen equivalent volume control buttons sliders or dialling actions.

Also in small form factor audio devices, such as Bluetooth earpieces, as not only are the volume control buttons typically out of sight when the device is in operation but the buttons are also small.

### SUMMARY OF THE VARIOUS EXAMPLES

Various examples of the present application aim to address the above problem.

There is provided according to a first aspect a method comprising: determining a force exerted on an apparatus for audio playback; and controlling a volume of an audio output through dependent on the force.

Determining a force exerted on an apparatus for audio playback may comprise determining a force for a region neighbouring an audio outlet.

Controlling a volume of an audio output dependent on the force may comprise controlling a volume of an audio output through the audio outlet.

Determining the force exerted may further comprise determining the magnitude of the force exerted, and wherein controlling the volume of the audio output comprises controlling the volume dependent on the magnitude of the force.

Controlling the volume of the audio output may comprise defining a volume level, wherein the volume level is directly dependent on the magnitude of the force.

Controlling the volume of the audio output may comprise controlling the rate of change of volume dependent on the magnitude of the force.

Determining a force exerted on the apparatus may comprise at least one of: determining a capacity value from a capacity sensor; determining a surface area value from a touch sensor; determining a micro-switch output; determining a electromechanical force sensor output; determining a force stress sensor output; and determining a transducer output.

The force may be exerted by the apparatus user's head when held to the user's ear.

According to a second aspect there is provided an apparatus comprising: a force sensor configured to determine a force exerted on the apparatus; and a volume controller configured to control a volume of an audio output dependent on the force.

The sensor may be further configured to determine a force exerted on the apparatus for a region of the apparatus neighbouring an audio outlet.

The volume controller may be further configured to control a volume of an audio output through the audio outlet dependent on the force.

The force sensor may be further configured to determine the magnitude of the force exerted, and wherein the volume controller may be configured to control the volume dependent on the magnitude of the force.

The volume controller may be configured to define a volume level, wherein the volume level is directly dependent on the magnitude of the force.

The volume controller may be configured to define the rate of change of volume dependent on the magnitude of the force.

The force sensor may comprise at least one of: a capacity sensor; a touch sensor; a micro-switch; an electromechanical force sensor; a force stress sensor; and a transducer.

The force may be exerted by the electronic device user's head when held to the user's ear.

The audio outlet may be the earpiece outlet.

According to a third aspect there is provided an apparatus comprising at least one processor and at least one memory including computer program code for one or more programs, the at least one memory and the computer program code configured to, with the at least one processor, cause the apparatus at least to perform: determining a force exerted on an apparatus; and controlling a volume of an audio output dependent on the force.

Determining a force exerted on an apparatus for audio playback may cause the apparatus to determine a force for a region neighbouring an audio outlet.

Controlling a volume of an audio output dependent on the force may cause the apparatus to control a volume of an audio output through the audio outlet.

Determining the force exerted may further cause the apparatus to perform determining the magnitude of the force exerted, and wherein controlling the volume of the audio output may cause the apparatus to perform controlling the volume dependent on the magnitude of the force.

Controlling the volume of the audio output may cause the apparatus to perform defining a volume level, wherein the volume level is directly dependent on the magnitude of the force.

Controlling the volume of the audio output may cause the apparatus to perform controlling the rate of change of volume dependent on the magnitude of the force.

Determining a force exerted on the apparatus may cause the apparatus to perform at least one of: determining a capacity value from a capacity sensor; determining a surface area value from a touch sensor; determining a micro-switch output; determining a electromechanical force sensor output; determining a force stress sensor output; and determining a transducer output.

The force may be exerted by the apparatus user's head when held to the user's ear.

According to a fourth aspect there is provided an apparatus comprising: means for determining a force exerted on an apparatus; and means for controlling a volume of an audio output dependent on the force.

The means for determining a force exerted on an apparatus for audio playback may comprise means for determining a force for a region neighbouring an audio outlet.

The means for controlling a volume of an audio output dependent on the force may comprise means for controlling the volume of the audio output through the audio outlet.

The means for determining the force exerted may further comprise means for determining the magnitude of the force exerted, and wherein the means for controlling the volume of the audio output may comprise means for controlling the volume dependent on the magnitude of the force.

The means for controlling the volume of the audio output may comprise means for defining a volume level, wherein the volume level is directly dependent on the magnitude of the force.

The means for controlling the volume of the audio output may comprise means for controlling the rate of change of volume dependent on the magnitude of the force.

The means for determining the force exerted on the apparatus may comprise at least one of: a capacity sensor; a touch sensor; a micro-switch; an electromechanical force sensor; a force stress sensor; and a transducer.

The force may be exerted by the apparatus user's head when held to the user's ear.

An apparatus may comprise means for performing the method of any of the herein disclosure.

A computer program product may cause an apparatus to perform the method of any of the herein disclosure.

According to a fifth aspect there is provided a computer-readable medium encoded with instructions that, when executed by a computer, perform: determining a force exerted on an apparatus for audio playback; and controlling a volume of an audio output dependent on the force.

Determining a force exerted on an apparatus for audio playback may cause the computer to further perform determining a force for a region neighbouring an audio outlet.

Controlling a volume of an audio output dependent on the force may cause the computer to further perform controlling a volume of an audio output through the audio outlet.

Determining the force exerted may further cause the computer to further perform determining the magnitude of the force exerted, and wherein controlling the volume of the audio output may cause the computer to further perform controlling the volume dependent on the magnitude of the force.

Controlling the volume of the audio output may cause the computer to further perform defining a volume level, wherein the volume level is directly dependent on the magnitude of the force.

Controlling the volume of the audio output may cause the computer to further perform controlling the rate of change of volume dependent on the magnitude of the force.

Determining a force exerted on the apparatus may cause the computer to further perform at least one of: determining a capacity value from a capacity sensor; determining a surface area value from a touch sensor; determining a micro-switch output; determining a electromechanical force sensor output; determining a force stress sensor output; and determining a transducer output.

An electronic device may comprise apparatus as described above.

A chipset may comprise apparatus as described above.

### BRIEF DESCRIPTION OF DRAWINGS

For better understanding of the present invention, reference will now be made by way of example to the accompanying drawings in which:

FIG. 1 shows schematically an apparatus employing embodiments of the application;

FIG. 2a shows schematically a touch screen audio device employing embodiments of the application;

FIG. 2b shows a clamshell form factor audio device employing embodiments of the application;

FIG. 3 shows schematically volume control apparatus according to some embodiments of the application;

FIGS. 4a to 4d show graphically example volume control relationships such as the force against volume step relationship employed in some embodiments of the application and the volume against time relationships employed in some other embodiments; and

FIG. 5 shows the operation of the volume control apparatus according to some embodiments of the application.

### DETAILED DESCRIPTION OF SOME EMBODIMENTS OF THE APPLICATION

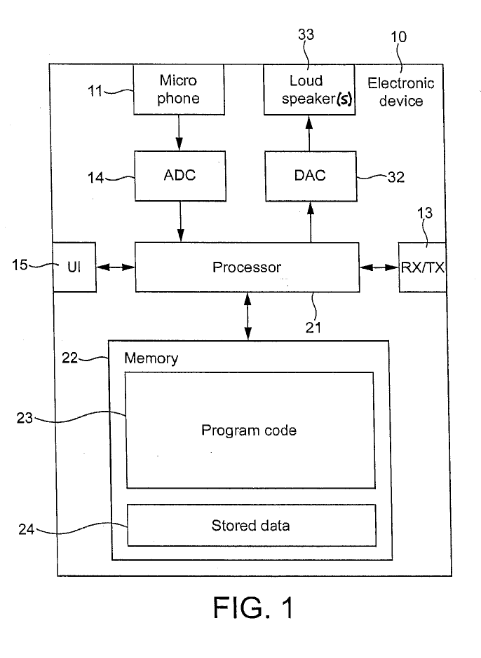

The following describes apparatus and methods for the provision of volume control in electronic devices. In this regard reference is first made to FIG. 1 which shows a schematic block diagram of an exemplary electronic device 10 or apparatus, which may incorporate volume control apparatus and/or methods according to some embodiments of the application.

The apparatus 10 may for example be a mobile terminal or user equipment for a wireless communication system. In other embodiments the apparatus may be an audio player such as an mp3 player, or media player such as an mp4 player. In other embodiments the apparatus can be a handset suitable of being held against the ear, a headset or any suitable device capable of presenting an audio signal to the user's ear when being located against or neighbouring the ear, such as a traditional landline phone handset.

The apparatus 10 can in some embodiments comprise a processor 21 which may be linked via a digital-to-analogue converter 32 to a playback speaker system 33 configured to provide a suitable audio playback. The playback speaker system 33 in some embodiments can comprise at least one suitable loudspeaker or transducer configured to operate in an earpiece mode, suitable for generating acoustic waves as the apparatus is located adjacent to or in contact with the ear. In some embodiments the at least one loudspeaker can be configured to operate in an integrated handsfree (IHF) mode, suitable for generating acoustic waves when the apparatus is used when the apparatus is not in close proximity to the ear.

In some embodiments when the apparatus and/or a part of the apparatus, for example the playback speaker, is a headphone or ear worn speaker (EWS) set the apparatus 10 can comprise a headphone connector or coupling for receiving the headphone or headset. In some embodiments the headphone connector or coupling can be configured to communicate to a headphone set or earplugs wirelessly, for example by a Bluetooth profile, or using a conventional wired connection. In some embodiments the audio output is generated through a conductive audio transmitter such as for example a ‘jawbone’ transducer or any other suitable transducer which generates the audio signal by physical conduction to the user. In some embodiments the playback speaker can be any suitable audio transducer apparatus. For example in some embodiments the audio signal is generated by an ‘audio display’, an example of which is the flat screen audio speaker.

The processor 21 can in some embodiments further linked to a transceiver (TX/RX) 13, to a user interface (UI) 15 and to a memory 22.

The processor 21 may be configured to execute various program codes. The implemented program codes in such embodiments comprise a volume control code or codes. The implemented program codes 23 in some embodiments can be stored for example in the memory 22 for retrieval by the processor 21 whenever needed. The memory 22 could further provide a section 24 for storing data, for example data that has been processed in accordance with the embodiments.

The volume control code or operations can in some embodiments be implemented at least partially in hardware and/or firmware.

In some embodiments the apparatus 10 comprises a user interface 15 which enables a user to input commands to the apparatus or electronic device 10, for example via a keypad, and/or to obtain information from the apparatus 10, for example via a display.

In some embodiments the apparatus 10 comprises a transceiver 13. The transceiver 13 enables communication with other apparatus, for example via a wireless communication network. The transceiver 13 in some embodiments can provide the wireless coupling between the apparatus and a wireless coupled playback speaker equipped with an associated transceiver.

The apparatus 10 can in some embodiments further comprise at least one microphone 11 for monitoring audio or speech. The apparatus 10 in such embodiments may further comprise an analogue-to-digital converter 14 configured to convert the input analogue audio signal into a digital audio signal and provide the digital audio signal to the processor 21.

Furthermore the apparatus 10 can in some embodiments receive a bit stream via the transceiver 13. The processor 21 in these embodiments may process the received audio signal data, and output the audio. The received stereo audio data can in some embodiments also be stored, instead of presented immediately, in the data section 24 of the memory 22, for instance for later presentation or forwarding to still another apparatus.

It is to be understood again that the structure of the apparatus 10 could be supplemented and varied in many ways and the above discussion is an example only of the possible components within a device suitable for employing embodiments of the application.

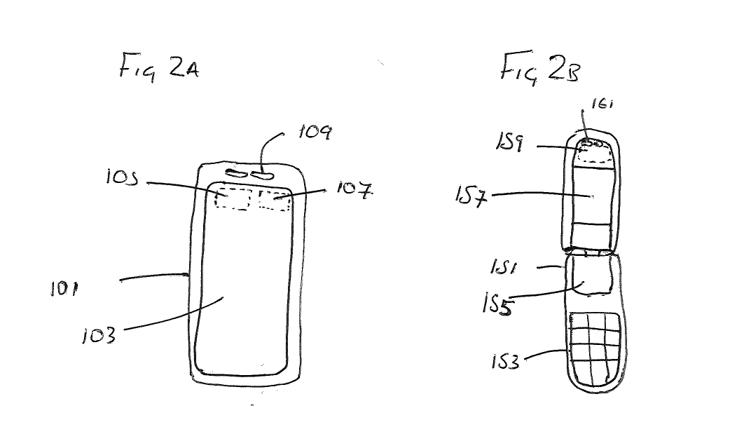

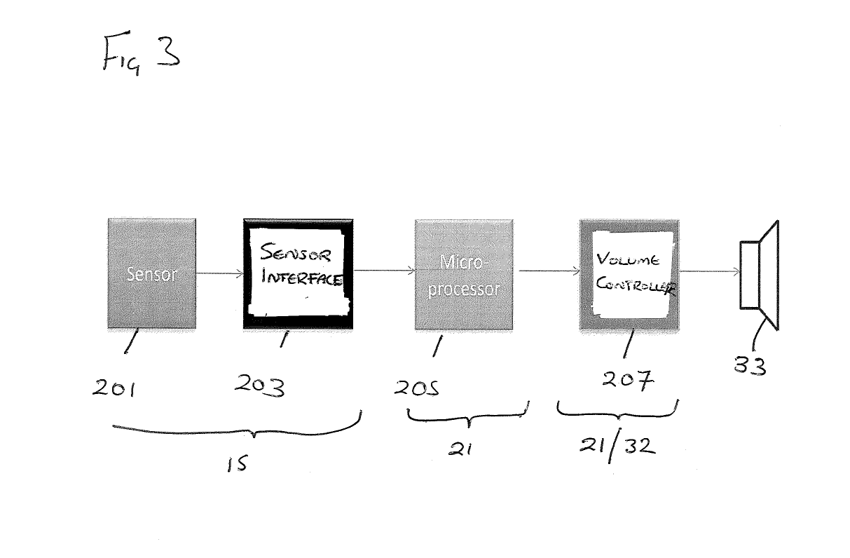

With respect to FIG. 2a, an example apparatus comprising volume control apparatus is shown. The example apparatus 101 has the form factor of a conventional touch screen device such as a touch screen mobile phone or media player. The apparatus 101 can comprise a display or display area 103 comprising any suitable touch screen technology, for example a capacitive touch screen sensor, or resistive touch screen sensor. Furthermore the example apparatus 101 can further comprise sound windows or outlets 109 configured to enable the device to output audio signals from transducers incorporated with the device. The sound outlets 109 are shown in FIG. 2a as being located neighbouring the touch screen adjacent to one of the short edges of the rectangular touch screen display area 103. However it would be appreciated that the sound outlets 109 in other embodiments could be located in any suitable position.

The example apparatus 101 can further comprise a volume control force sensor. In this example, as shown in FIG. 2a, the touch screen display area 103 has regions which can perform or be employed as force sensors. In this example the regions 105 and 107 of the touch screen display operating force sensors are located neighbouring the sound outlets.

The volume control force sensor can be implemented by using a touch screen display sensor or touch sensitive device as it would be understood that the greater the force of an object on the display, the larger the surface area of the contact body is likely to be. Therefore the contact area detected by the sensor can be used as a measure of the force on the sensor. For example with regards to the mobile phone or user equipment shown in FIG. 2a, light force on the phone or user equipment when held to the ear would produce a surface contact area with a first value and an increased force as the phone is pressed against the ear would produce a larger value as the surface contact area would increase as the ear would flatten against the touch sensitive surface. Furthermore not only does the contact area increase with an increased force but also the capacitive coupling changes and can be detected.

Although the volume control force sensor in the above embodiments is shown as two regions on the touch screen display it would be understood that any suitable number, arrangement or shape of region can be monitored for force. Furthermore as discussed herein, although in the above example the force sensor is the touch screen input and suitable force sensor can be employed. For example in some embodiments the touch screen can be located on the electronic device in a floating chassis which can be displaced in response to force. This displacement can be determined such as by a piezoelectric sensor or by any suitable transducer means.

With respect to FIG. 2b, a “flip phone” or clamshell form factor mobile phone or example audio apparatus is shown suitable for implementing embodiments of the application. The clamshell example 151 apparatus can comprise a lower portion with a keypad 153, and a control selection area 155, a hinge arrangement coupling the lower portion to the upper portion, and an upper portion with a display 157 for displaying images to the user, at least one sound outlet or sound windows for providing audio to the user 161 and furthermore a volume control force sensor 159.

The volume control force sensor 159 can in a manner similar to the example shown in FIG. 2a be any suitable sensor. Therefore in some embodiments the force sensor can be a touch interface region or a physical force sensor sensing the force directly or indirectly. For example in some embodiments the volume control force sensor can comprise a micro-switch directly sensing the application of force. In some embodiments the micro-switch can have a binary switching operation, in other words the force on the volume control sensor operates either on or off. This on or off indication can as is described herein be used to control the volume output by the apparatus. For example the off indication could be used by the volume controller to control the output to provide a ‘normal’ volume, in other words a volume level set by the user prior to placing the device close to the head and the on indication could be used by the volume controller to provide a ‘loud’ or ‘boosted’ volume to increase the volume when required.

In some other embodiments the force sensor can be a multi-level or continuous range force sensor, in other words producing an output proportional to the force experienced by the sensor. A suitable example of such a force sensor could in some embodiments be a piezoelectric beam sensor configured to generate a voltage dependent on the force causing the beam to bend. In some embodiments the sensor could be implemented within the hinge of the clamshell form factor device so that force causes the upper portion of the device to move relative to the lower portion held by the user. In such embodiments the hinge can be resiliently biased.

The volume control force sensor can in some further embodiments be a capacitive force sensor whereby force on a first plate or region moves the first plate closer to a second plate and therefore produces an output proportional to the force.

In some other embodiments the volume control force sensor can be a resistive wire strain sensor producing an output proportional on the strain on the wire sensor.

In some embodiments the force sensor can be any suitable electro-mechanical transducer. For example the force sensor could be a spring loaded potentiometer. In such embodiments the force sensor can directly control the volume level. For example the resistor of the potentiometer can attenuate the volume directly of the speaker, or of the amplifier for the speaker.

Any other suitable mechanical force sensor or virtual force sensor could be implemented in some other embodiments of the application.

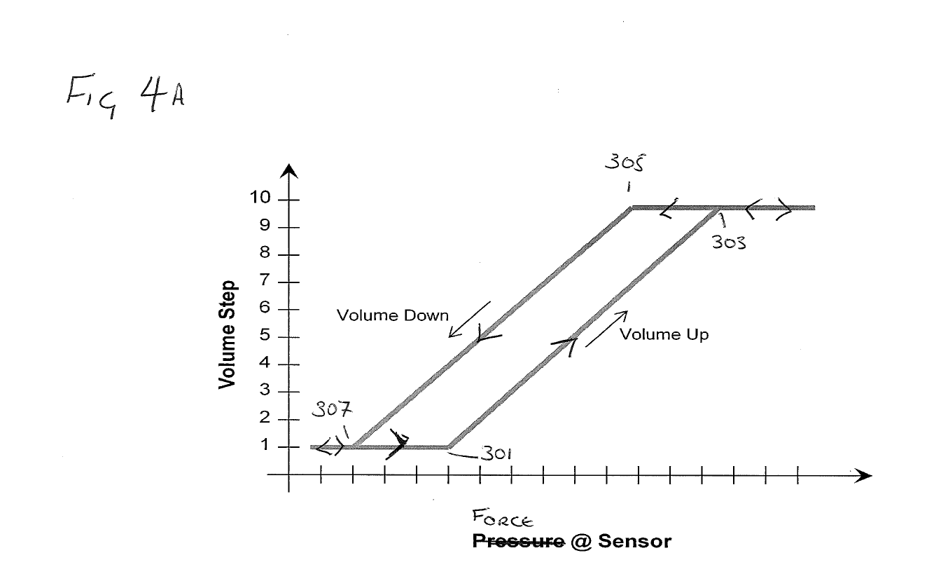

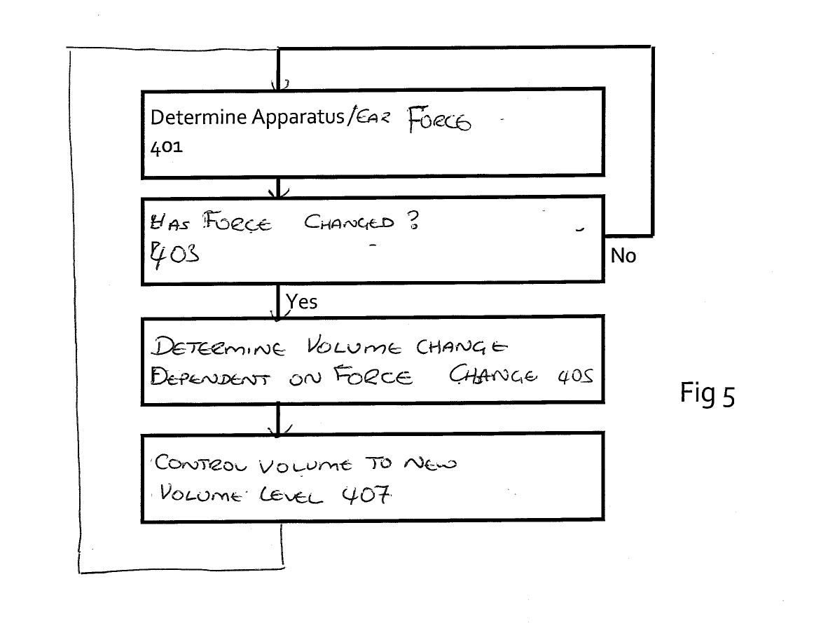

With respect to FIG. 3 a schematic functional view of the volume control apparatus, for example the apparatus shown in FIG. 2a, is shown in further detail. Furthermore with respect to FIG. 5 the operation of such volume control apparatus is shown as a flow diagram.

The volume control apparatus in some embodiments comprises a sensor 201. The sensor 201 in some embodiments comprises the force sensor can be as described herein any suitable force sensing means configured to produce an output dependent on the force experienced by the device from the user.

In some embodiments the force sensor is configured to determine the force exerted on the apparatus for a region neighbouring the audio outlet. For example in the touch example shown in FIG. 2a the force sensor can monitor the force exerted on the touch screen neighbouring the earpiece. The audio outlet can in some embodiments be an audio window or earpiece hole, holes or slits acoustically coupling the audio transducer to the environment. For example in both FIGS. 2a and 2b the audio outlet can be the pair of acoustic slits shown. However in some embodiments, for example where the audio transducer is a flat surface transducer or audio display, or is part of the apparatus casing such as a resonant surface transducer then the audio outlet is the surface which outputs the acoustic waves and provides the audio outlet for the apparatus.

The sensor 201 is configured to output force indication values to a sensor interface 203. In some embodiments the sensor 201 can further comprise other sensed characteristics for the apparatus. For example in some embodiments the sensor 201 can further comprise an orientation sensor configured to indicate whether the apparatus is being held in defined direction or orientation. The orientation sensor output can in some embodiments be passed the microprocessor or volume controller and the volume control operations as described herein performed when the microprocessor or volume controller determines that the apparatus is being held in a defined direction, for example an ‘upright’ direction, rather than a ‘flat’ direction, and so prevent accidental operation of the volume control when not needed, for example accidentally pressing the force sensor when the apparatus is on the desk or in the pocket. In some other embodiments the sensor 201 can monitor the mode of operation of the apparatus and the microprocessor or volume controller perform the volume control operations when the apparatus is in a defined mode, for example in earpiece mode compared to hands free mode.

In some embodiments the volume control apparatus comprises a sensor interface 203. The sensor interface 203 can be configured to receive the sensor data from the force sensor 201 and to output the sensor data in a suitable format. In some embodiments where the sensor 201 is a touch screen the sensor interface 203 can monitor the regions neighbouring the audio outlets so to produce a useable ‘force’ value from the touch screen output.

The sensor interface 203 in some embodiments is furthermore a sensor controller configured to control the sensor. For example where the sensor 201 is a piezoelectric sensor outputting a voltage level, the sensor interface 203 can be configured to bias the piezoelectric sensor (as well as interpreting the voltage output from the sensor). In some embodiments the sensor interface 203 can be configured to perform an analogue-to-digital conversion of the sensor 201 output to produce a data value in a suitable format for further processing.

The output of the sensor interface controller can be passed to the microprocessor 205.

In some embodiments the sensor 201 and sensor interface 203 can be implemented or understood to be part of the user interface 15. In some embodiments the sensor and sensor interface can be implemented as a single component or element. For example the sensor could be a micro switch which outputs a force sensor output when the switch is enabled by a threshold force, and where the switch is biased or controlled itself.

The determination of the force value is shown in FIG. 5 by step 401.

In some embodiments the volume control apparatus comprises a microprocessor or processor which on receiving the sensor force value from the sensor interface or sensor can then determine whether or not the force has sufficiently changed over time to change the volume. In some embodiments the microprocessor performs force monitoring which employs at least one threshold value such that if the force sensor value changes within a determined period by the determined threshold amount (a differential determination) or the force sensor value reaches or passes the determined threshold amount (an absolute determination) the microprocessor initiates a volume change operation.

Thus in some embodiments when the microprocessor 205 determines that the force sensor has not changed sufficiently, the operation passes back to a further determination of the force value.

This can be seen in FIG. 5 by the check step 403 which loops back to the determination of the force step shown in FIG. 5 by step 401.

Furthermore when the force check step determines that the force has changed sufficiently, the operation passes to the step 405 which initiates a volume change operation.

The microprocessor 205 can furthermore in some embodiments determine the volume level change dependent on the force sensor value, for example the force sensor value change. The microprocessor 205 can determine the volume level change dependent on the force sensor value in any suitable manner.

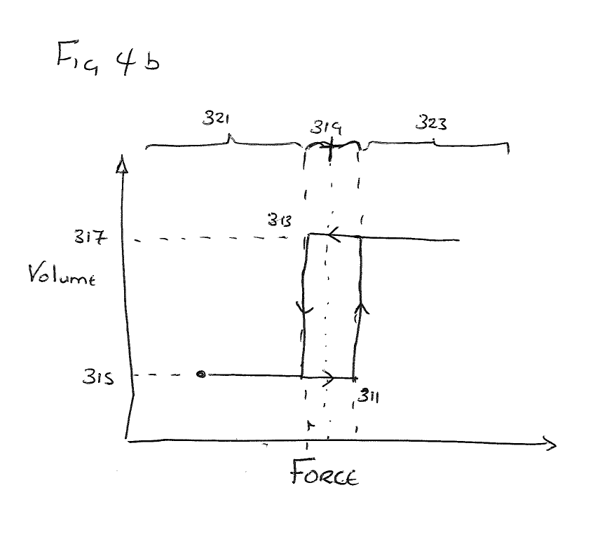

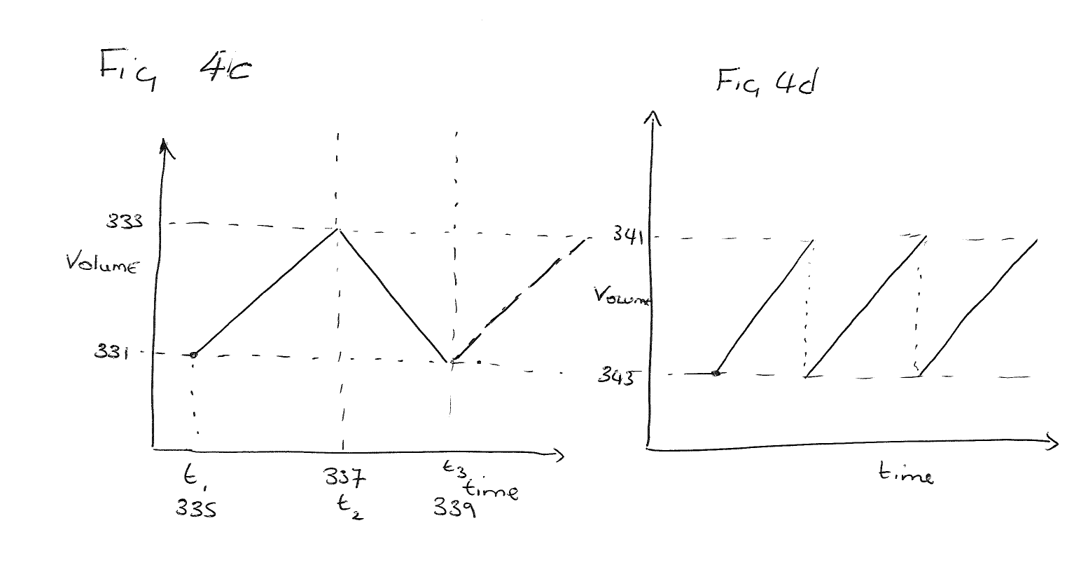

For example in some embodiments the microprocessor 205 can determine volume level change such that the volume can be increased as the determined force is increased and the volume level is decreased as the determined force is decreased. This type of volume change operation is shown graphically in FIG. 4 as the volume step or level against force characteristics. In this example, a minimum volume is defined from a zero force sensor level up to a first force threshold 301. The microprocessor 102 can furthermore be configured to define a first relationship between volume and force as detected force sensor levels increase the volume level also increases up to a second force threshold 303 at which point a maximum volume level is defined. Similarly to reduce the volume when the volume is at a maximum level, a third force threshold 305 is defined below the second force threshold from which the processor defines a second relationship between volume level and force such that as the detected force decreases the volume level is decreased to a minimum level when the force reaches a fourth threshold value 307 which is lower than the first threshold.

In other words the microprocessor 102 can be configured to output a volume level control value dependent on the force sensor but using hysteresis to prevent too rapid changes in volume.

In some embodiments the microprocessor 102 can be configured to determine volume change or rate of volume change dependent on the force value. Thus a small force increase detected at the microprocessor determines a slow volume level increase, whereas a larger force increase detected at the processor determines a faster volume level increase.

Therefore in some embodiments the volume level or change in volume level is dependent on the force sensor level, for example a first force sensor level maintains a current volume, a lower force sensor level lowers the volume and a higher force sensor level increases the volume.

Although in some embodiments the relationship between force sensor values and defined volume levels has a high degree of correlation the microprocessor can in some embodiments define volume changes using any suitable volume change relationship between detected force and defined volume level.

For example as described herein the detected force can be used to define a threshold or threshold region over which a defined ‘normal’ volume level is changed to a ‘boost’ or ‘loud’ volume level. In some embodiments the ‘normal’ and ‘loud’ volume levels can be defined either manually or automatically. An example of this type of volume control can be shown with respect to FIG. 4b wherein the ‘normal’ volume level 315 can be defined when the output by the switch/sensor indicates an ‘off’ position or region 321 and the ‘loud’ or ‘boosted’ volume level 317 can be defined when the output by the switch/sensor indicates an ‘on’ position or region 323. In the example shown in FIG. 4b an intermediate position or region 319 is defined (as shown by force outputs 313 and 311) such that the volume is not ‘bounced’ between the ‘on’ and ‘off’ positions.

In some other embodiments the microprocessor 205 can be configured to define the volume such that the volume change is a series of up and down ramp changes wherein the ramping of the volume occurs when the detected force is greater than a defined threshold.

This can be shown for example with reference to FIG. 4c where the microprocessor can define an initial, current or a minimum volume level 331 at a first time t₁ 335. As force is detected the microprocessor could increase the volume at a defined rate of change until the maximum volume level 333 is reached at time t₂ 337. If the force is further maintained then the microprocessor could then decrease the volume at a further defined rate of change until the volume level reaches the minimum volume level at time t₃ 339 and could further repeat the alternately increasing and decreasing of the volume until the force is released on the sensor. When the detected force is released (in other words when the force sensor level is below the significant or threshold level) the microprocessor stops the loop volume change operation.

In some embodiments the microprocessor 205 can implement a volume change operation as shown in FIG. 4d wherein whilst the force is maintained the volume is monotonically increased (or decreased) at a defined rate of change and when it reaches the volume maximum 341 (or minimum), the microprocessor 205 resets the volume level to the minimum 343 (or maximum) volume value and then increases the volume level in the same way until the determined force is below the threshold level.

Although these examples of volume control are shown it would be understood that any suitable volume control could be implemented dependent on the force sensor input as the device is held neighbouring or against the head.

The microprocessor can then output this volume control value to a volume controller 207.

The determination of volume change dependent on force change can be shown in FIG. 5 by step 405.

In some embodiments the sensor interface 203 and microprocessor 205 functionality can be implemented within a single device wherein the sensor outputs values directly to a processor and furthermore the sensor is controlled by the same microprocessor.

The volume controller 207 can be configured to receive the signal from the microprocessor and control the volume to be output by the speaker 33. The volume controller 207 can, for example, be a controllable amplifier, or variable resistor suitably controlled by the microprocessor 205.

In some embodiments as described herein the operation of the microprocessor and volume controller 207 can be implemented as a volume controller configured to receive at least a force indication or information from a force sensor and be configured to control the volume of an audio output through an audio outlet neighbouring or adjacent to the location where the force is exerted.

In some embodiments the microprocessor and volume controller can furthermore be implemented as any suitable means for controlling the volume (or signal level or power level) of the audio output dependent on the force exerted on the apparatus for a region neighbouring the audio output.

The implementation of the change in volume level to the speaker or transducer is shown in FIG. 5 by step 407.

When the change in volume level the process can in some embodiments pass back to the first operation of determining the force value as can be seen in FIG. 5.

By using such embodiments of the application, the user can therefore control the volume without requiring the need to search for the volume control switches, or other interface elements. Furthermore this type of volume control according to embodiments of the application exploits the typical response of the user to loud or quiet audio signals. In other words it is typical that when the user experiences too high a volume, they are likely to move the phone or device away from their ear and thus decrease the force on the device, whereas if the audio is too quiet, the typical user will attempt to press the device closer to the ear, thus increasing the force on the device.

Furthermore by implementing the volume control in such a manner, specific volume control keys are no longer necessary which saves costs, development time and allows the phone to assemble quicker and easier due to the reduction in the number of components.

Although the above examples describe embodiments of the invention operating within an electronic device 10 or apparatus, it would be appreciated that the invention as described below may be implemented as part of any audio processor. Thus, for example, embodiments of the invention may be implemented in an audio processor which may implement audio processing over fixed or wired communication paths.

Thus user equipment may comprise an audio processor such as those described in embodiments of the invention above.

In general, the various embodiments of the invention may be implemented in hardware or special purpose circuits, software, logic or any combination thereof. For example, some aspects may be implemented in hardware, while other aspects may be implemented in firmware or software which may be executed by a controller, microprocessor or other computing device, although the invention is not limited thereto. While various aspects of the invention may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

Thus at least some embodiments may be an apparatus comprising at least one processor and at least one memory including computer program code the at least one memory and the computer program code configured to, with the at least one processor, cause the apparatus at least to perform: determining a force exerted on an apparatus for a region neighbouring an audio outlet; and controlling a volume of an audio output through the audio outlet dependent on the force.

The embodiments of this invention may be implemented by computer software executable by a data processor of the mobile device, such as in the processor entity, or by hardware, or by a combination of software and hardware. Further in this regard it should be noted that any blocks of the logic flow as in the Figures may represent program steps, or interconnected logic circuits, blocks and functions, or a combination of program steps and logic circuits, blocks and functions. The software may be stored on such physical media as memory chips, or memory blocks implemented within the processor, magnetic media such as hard disk or floppy disks, and optical media such as for example DVD and the data variants thereof, CD.

The memory may be of any type suitable to the local technical environment and may be implemented using any suitable data storage technology, such as semiconductor-based memory devices, magnetic memory devices and systems, optical memory devices and systems, fixed memory and removable memory. The data processors may be of any type suitable to the local technical environment, and may include one or more of general purpose computers, special purpose computers, microprocessors, digital signal processors (DSPs), application specific integrated circuits (ASIC), gate level circuits and processors based on multi-core processor architecture, as non-limiting examples.

Embodiments of the inventions may be practiced in various components such as integrated circuit modules. The design of integrated circuits is by and large a highly automated process. Complex and powerful software tools are available for converting a logic level design into a semiconductor circuit design ready to be etched and formed on a semiconductor substrate.

Programs, such as those provided by Synopsys, Inc. of Mountain View, Calif. and Cadence Design, of San Jose, Calif. automatically route conductors and locate components on a semiconductor chip using well established rules of design as well as libraries of pre-stored design modules. Once the design for a semiconductor circuit has been completed, the resultant design, in a standardized electronic format (e.g., Opus, GDSII, or the like) may be transmitted to a semiconductor fabrication facility or “fab” for fabrication.

As used in this application, the term ‘circuitry’ refers to all of the following:
(a) hardware-only circuit implementations (such as implementations in only analogue and/or digital circuitry) and
(b) to combinations of circuits and software (and/or firmware), such as: (i) to a combination of processor(s) or (ii) to portions of processor(s)/software (including digital signal processor(s)), software, and memory(ies) that work together to cause an apparatus, such as a mobile phone or server, to perform various functions and
(c) to circuits, such as a microprocessor(s) or a portion of a microprocessor(s), that require software or firmware for operation, even if the software or firmware is not physically present.

This definition of ‘circuitry’ applies to all uses of this term in this application, including any claims. As a further example, as used in this application, the term ‘circuitry’ would also cover an implementation of merely a processor (or multiple processors) or portion of a processor and its (or their) accompanying software and/or firmware. The term ‘circuitry’ would also cover, for example and if applicable to the particular claim element, a baseband integrated circuit or applications processor integrated circuit for a mobile phone or similar integrated circuit in server, a cellular network device, or other network device.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims.

1-43. (canceled)

44. A method comprising:
determining a force exerted on an apparatus for audio playback; and
controlling a volume of an audio output dependent on the force.

45. The method as claimed in claim 44, wherein determining a force exerted on an apparatus for audio playback comprises determining a force for a region neighbouring an audio outlet.

46. The method as claimed in claim 45, wherein controlling a volume of an audio output dependent on the force comprises controlling a volume of an audio output through the audio outlet.

47. The method as claimed in claim 44, wherein determining the force exerted further comprises determining the magnitude of the force exerted, and wherein controlling the volume of the audio output comprises controlling the volume dependent on the magnitude of the force.

48. The method as claimed in claim 47, wherein controlling the volume of the audio output comprises defining a volume level, wherein the volume level is directly dependent on the magnitude of the force.

49. The method as claimed in claim 47, wherein controlling the volume of the audio output comprises controlling the rate of change of volume dependent on the magnitude of the force.

50. The method as claimed in claim 44, wherein determining a force exerted on the apparatus comprises at least one of:
determining a capacity value from a capacity sensor;
determining a surface area value from a touch sensor;
determining a micro-switch output;
determining a electromechanical force sensor output;
determining a force stress sensor output; and
determining a transducer output.

51. The method as claimed in claim 44, wherein the force is exerted by the apparatus when held to the user's ear.

52. An apparatus comprising:
a sensor configured to determine a force exerted on the apparatus; and
a volume controller configured to control a volume of an audio output dependent on the force.

53. The apparatus as claimed in claim 52, wherein the sensor is further configured to determine a force exerted on the apparatus for a region of the apparatus neighbouring an audio outlet.

54. The apparatus as claimed in claim 53, wherein the volume controller is further configured to control a volume of an audio output through the audio outlet dependent on the force

55. The apparatus as claimed in claim 52, wherein the sensor is further configured to determine the magnitude of the force exerted, and wherein the volume controller is configured to control the volume dependent on the magnitude of the force.

56. The apparatus as claimed in claim 55, wherein the volume controller is configured to define a volume level, wherein the volume level is directly dependent on the magnitude of the force.

57. The apparatus as claimed in claim 55, wherein the volume controller is configured to define the rate of change of volume dependent on the magnitude of the force.

58. The apparatus as claimed in claim 52, wherein the force sensor comprises at least one of:
a capacity sensor;
a touch sensor;
a micro-switch;
an electromechanical force sensor;
a force stress sensor; and
a transducer.

59. The apparatus as claimed in claim 52, wherein the force is exerted by the electronic device when held to the user's ear.

60. The apparatus as claimed in claim 53, wherein the audio outlet is the earpiece outlet.

61. A computer-readable medium encoded with instructions that, when executed by a computer, perform:
determining a force exerted on an apparatus for audio playback; and
controlling a volume of an audio output dependent on the force.

62. The computer-readable medium as claimed in claim 61, wherein determining a force exerted on an apparatus for audio playback causes the computer to further perform determining a force for a region neighbouring an audio outlet.

63. The computer-readable medium as claimed in claim 62, wherein controlling a volume of an audio output dependent on the force causes the computer to further perform controlling a volume of an audio output through the audio outlet.
